(19) United States
(12) Patent Application Publication
(10) Pub. No.: US 2025/0290880 A1
(43) Pub. Date: Sep. 18, 2025

(54) METHOD TO DETERMINE PORE THROAT SIZE DISTRIBUTION OF ROCKS BY NUCLEAR MAGNETIC RESONANCE

(71) Applicant: SAUDI ARABIAN OIL COMPANY, Dhahran (SA)

(72) Inventors: Jun Gao, Dhahran (SA); Hyung Tae Kwak, Dhahran (SA)

(73) Assignee: SAUDI ARABIAN OIL COMPANY, Dhahran (SA)

(21) Appl. No.: 18/606,900

(22) Filed: Mar. 15, 2024

(51) Int. Cl. G01N 24/08; G01N 15/08; G01R 33/30; G01R 33/50

(52) U.S. Cl. CPC G01N 24/081; G01N 15/088; G01R 33/30; G01R 33/50

(57) ABSTRACT

A method for determining a pore throat size distribution in a rock sample includes saturating the rock sample with a fluid to a maximum saturation, acquiring a first set of nuclear magnetic resonance (NMR) measurements of the rock sample, generating based on a first T2 distribution of the first set of NMR measurements a first saturation profile and a first set of slice measurements, obtaining a peak T2 measurement and an average pore throat size measurement by conducting a subsequent NMR measurement procedure, repeating obtaining a peak T2 measurement until the rock sample has a minimum saturation, obtaining a fit function by fitting the average pore throat size measurements to the peak T2 measurements, and generating a pore throat size distribution from the first T2 distribution. A computer system for determining a pore size distribution in a rock sample includes a processor and a memory coupled to the processor.

### BACKGROUND

Pore size distribution is an important property of the microscopic pore space of porous oil and gas reservoir rocks. Hydrocarbon fluids in microscopic spaces in porous reservoir sedimentary rocks flow to the wellbore for extraction during production. Accurate quantification of such microscopic spaces is essential to understand the rock storage capacity and ability for the fluids to flow during production operations. These spaces consist of microscopic and interconnected pores that are formed during deposition and subsequently modified by diagenesis. Different methods, such as mercury injection capillary pressure (MICP) are used to measure the pore size distribution in porous reservoir sedimentary rocks.

Different methods are based on different pore space models and obtain different pore size distributions of the same complex irregular pore space indicated by the 3D microCT images. A simple capillary bundle model has been often used to introduce basic concepts of porous media. A pore network model has been used to understand the connectivity of pore bodies through pore throats. All models are simplified representations of actual pore space with certain assumptions. For a very complex pore space, the identification of individual pore bodies and throats could be very challenging.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method for determining a pore throat size distribution in a rock sample, which includes saturating the rock sample with a fluid to a maximum saturation, acquiring a first set of nuclear magnetic resonance (NMR) measurements of the rock sample, generating based on a first T2 distribution of the first set of NMR measurements a first saturation profile and a first set of slice measurements, obtaining a peak T2 measurement and an average pore throat size measurement by conducting a subsequent NMR measurement procedure, repeating obtaining a peak T2 measurement until the rock sample has a minimum saturation, obtaining a fit function by fitting the average pore throat size measurements to the peak T2 measurements, and generating, using the fit function, a pore throat size distribution from the first T2 distribution.

In another aspect, embodiments disclosed herein relate to a computer system for determining a pore size distribution in a rock sample, which includes a processor and a memory coupled to the processor. The memory stores instructions, that when executed, include functionality for acquiring a first set of nuclear magnetic resonance (NMR) measurements of the rock sample wherein the rock sample is saturated with a fluid to a maximum saturation, generating based on a first T2 distribution of the first set of NMR measurements a first saturation profile and a first set of spatial T2 distributions, obtaining a peak T2 measurement by conducting a subsequent measurement procedure, repeating conducting the subsequent procedure until saturation of the rock sample has a minimum saturation, obtaining a fit function by fitting the average pore throat size measurements to the peak T2 measurements, and generating a pore throat size distribution from the first T2 distribution using the fit function.

Other aspects and advantages of the claimed subject matter will be apparent from the following description and the appended claims.

### BRIEF DESCRIPTION OF DRAWINGS

FIGS. 1, 2, and 3 show systems in accordance with one or more embodiments.

FIG. 4 shows a schematic of measurements in accordance with one or more embodiments.

FIG. 5 shows a flowchart in accordance with one or more embodiments.

FIGS. 6A and 6B show a computing system in accordance with one or more embodiments.

FIGS. 7, 8, 9, 10, and 11 show exemplary results in accordance with one or more embodiments.

### DETAILED DESCRIPTION

Specific embodiments of the disclosure will now be described in detail with reference to the accompanying figures. Like elements in the various figures are denoted by like reference numerals for consistency.

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Embodiments of the invention provide a method and system for determining a pore throat size distribution of a rock sample using capillary measurements based on a nuclear magnetic resonance method. The current method of obtaining a pore size distribution takes advantage of multiple NMR measurements and conducts comprehensive data analysis. A link between pore throat size and T2 is obtained from experiments instead of a mathematical match of two different curves assuming linear or power relationships. The determination of pore throat size distribution is conducted on a single rock sample eliminating the potential effect of core scale heterogeneity.

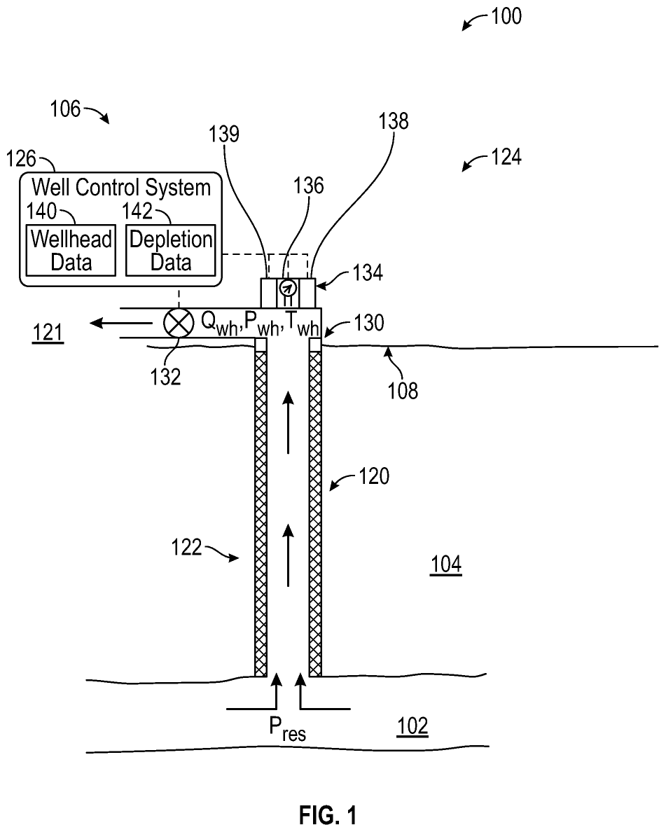

Turning to FIG. 1, FIG. 1 shows a schematic diagram in accordance with one or more embodiments. As shown in FIG. 1, FIG. 1 illustrates a well environment (100) that includes a hydrocarbon reservoir (“reservoir”) (102) located in a subsurface hydrocarbon-bearing formation (“formation”) (104) and a well system (106). The hydrocarbon-bearing formation (104) may include a porous or fractured rock formation that resides underground, beneath the earth's surface (“surface”) (108). In the case of the well system (106) being a hydrocarbon well, the reservoir (102) may include a portion of the hydrocarbon-bearing formation (104). The hydrocarbon-bearing formation (104) and the reservoir (102) may include different layers of rock having varying characteristics, such as varying degrees of permeability, porosity, capillary pressure, and resistivity. In the case of the well system (106) being operated as a production well, the well system (106) may facilitate the extraction of hydrocarbons (or “production”) from the reservoir (102).

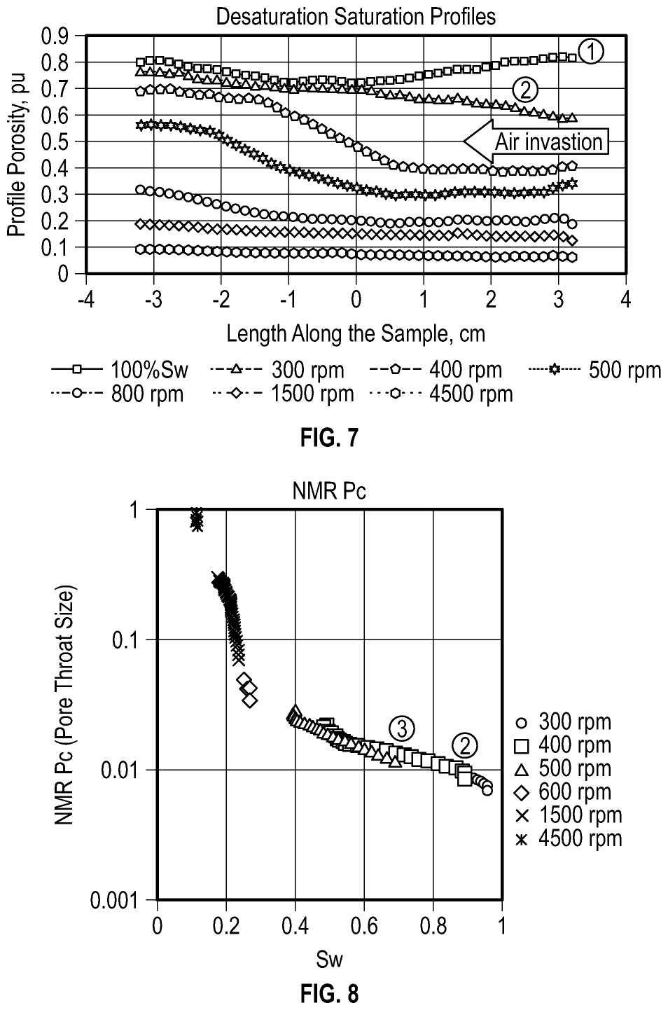

In one or more embodiments, the well system (106) includes a wellbore (120), a well sub-surface system (122), a well surface system (124), and a well control system (“control system”) (126). The control system (126) may control various operations of the well system (106), such as well production operations, well completion operations, well maintenance operations, and reservoir monitoring, assessment and development operations. In one or more embodiments, the control system (126) includes a computer system that is the same as or similar to that of computer system (700) described below in FIGS. 7A and 7B and the accompanying description.

The wellbore (120) may include a bored hole that extends from the surface (108) into a target zone of the hydrocarbon-bearing formation (104), such as the reservoir (102). An upper end of the wellbore (120), terminating at or near the surface (108), may be referred to as the “up-hole” end of the wellbore (120), and a lower end of the wellbore, terminating in the hydrocarbon-bearing formation (104), may be referred to as the “down-hole” end of the wellbore (120). The wellbore (120) may facilitate the circulation of drilling fluids during drilling operations, the flow of hydrocarbon production (“production”) (121) (e.g., oil and gas) from the reservoir (102) to the surface (108) during production operations, the injection of substances (e.g., water) into the hydrocarbon-bearing formation (104) or the reservoir (102) during injection operations, or the communication of monitoring devices (e.g., logging tools) into the hydrocarbon-bearing formation (104) or the reservoir (102) during monitoring operations (e.g., during in situ logging operations).

In one or more embodiments, during operation of the well system (106), the control system (126) collects and records wellhead data (140) for the well system (106). The wellhead data (140) may include, for example, a record of measurements of wellhead pressure (P_{wh}) (e.g., including flowing wellhead pressure), wellhead temperature (T_{wh}) (e.g., including flowing wellhead temperature), wellhead production rate (Q_{wh}) over some or all of the life of the well (106), and water cut data. In one or more embodiments, the measurements are recorded in real-time, and are available for review or use within seconds, minutes or hours of the condition being sensed (e.g., the measurements are available within 1 hour of the condition being sensed). In such an embodiment, the wellhead data (140) may be referred to as “real-time” wellhead data (140). Real-time wellhead data (140) may enable an operator of the well (106) to assess a relatively current state of the well system (106), and make real-time decisions regarding development of the well system (106) and the reservoir (102), such as on-demand adjustments in regulation of production flow from the well.

In one or more embodiments, the well sub-surface system (122) includes casing installed in the wellbore (120). For example, the wellbore (120) may have a cased portion and an uncased (or “open-hole”) portion. The cased portion may include a portion of the wellbore having casing (e.g., casing pipe and casing cement) disposed therein. The uncased portion may include a portion of the wellbore not having casing disposed therein. In one or more embodiments, the casing includes an annular casing that lines the wall of the wellbore (120) to define a central passage that provides a conduit for the transport of tools and substances through the wellbore (120). For example, the central passage may provide a conduit for lowering logging tools into the wellbore (120), a conduit for the flow of production (121) (e.g., oil and gas) from the reservoir (102) to the surface (108), or a conduit for the flow of injection substances (e.g., water) from the surface (108) into the hydrocarbon-bearing formation (104). In one or more embodiments, the well sub-surface system (122) includes production tubing installed in the wellbore (120). The production tubing may provide a conduit for the transport of tools and substances through the wellbore (120). The production tubing may, for example, be disposed inside casing. In such an embodiment, the production tubing may provide a conduit for some or all of the production (121) (e.g., oil and gas) passing through the wellbore (120) and the casing.

In one or more embodiments, the well surface system (124) includes a wellhead (130). The wellhead (130) may include a rigid structure installed at the “up-hole” end of the wellbore (120), at or near where the wellbore (120) terminates at the Earth's surface (108). The wellhead (130) may include structures for supporting (or “hanging”) casing and production tubing extending into the wellbore (120). Production (121) may flow through the wellhead (130), after exiting the wellbore (120) and the well sub-surface system (122), including, for example, the casing and the production tubing. In one or more embodiments, the well surface system (124) includes flow regulating devices that are operable to control the flow of substances into and out of the wellbore (120). For example, the well surface system (124) may include one or more production valves (132) that are operable to control the flow of production (134). For example, a production valve (132) may be fully opened to enable unrestricted flow of production (121) from the wellbore (120), the production valve (132) may be partially opened to partially restrict (or “throttle”) the flow of production (121) from the wellbore (120), and production valve (132) may be fully closed to fully restrict (or “block”) the flow of production (121) from the wellbore (120), and through the well surface system (124).

In one or more embodiments, the wellhead (130) includes a choke assembly. For example, the choke assembly may include hardware with functionality for opening and closing the fluid flow through pipes in the well system (106). Likewise, the choke assembly may include a pipe manifold that may lower the pressure of fluid traversing the wellhead. As such, the choke assembly may include set of high pressure valves and at least two chokes. These chokes may be fixed or adjustable or a mix of both. Redundancy may be provided so that if one choke has to be taken out of service, the flow can be directed through another choke. In one or more embodiments, pressure valves and chokes are communicatively coupled to the well control system (126). Accordingly, a well control system (126) may obtain wellhead data regarding the choke assembly as well as transmit one or more commands to components within the choke assembly in order to adjust one or more choke assembly parameters.

Keeping with FIG. 1, in one or more embodiments, the well surface system (124) includes a surface sensing system (134). The surface sensing system (134) may include sensors for sensing characteristics of substances, including production (121), passing through or otherwise located in the well surface system (124). The characteristics may include, for example, pressure, temperature and flow rate of production (121) flowing through the wellhead (130), or other conduits of the well surface system (124), after exiting the wellbore (120).

In one or more embodiments, the surface sensing system (134) includes a surface pressure sensor (136) operable to sense the pressure of production (151) flowing through the well surface system (124), after it exits the wellbore (120). The surface pressure sensor (136) may include, for example, a wellhead pressure sensor that senses a pressure of production (121) flowing through or otherwise located in the wellhead (130). In one or more embodiments, the surface sensing system (134) includes a surface temperature sensor (138) operable to sense the temperature of production (151) flowing through the well surface system (124), after it exits the wellbore (120). The surface temperature sensor (138) may include, for example, a wellhead temperature sensor that senses a temperature of production (121) flowing through or otherwise located in the wellhead (130), referred to as “wellhead temperature” (T_{wh}). In one or more embodiments, the surface sensing system (134) includes a flow rate sensor (139) operable to sense the flow rate of production (151) flowing through the well surface system (124), after it exits the wellbore (120). The flow rate sensor (139) may include hardware that senses a flow rate of production (121) (Q_{wh}) passing through the wellhead (130).

In one or more embodiments, the well system (106) includes a reservoir simulator (160). For example, the reservoir simulator (160) may include hardware and/or software with functionality for generating one or more reservoir models regarding the hydrocarbon-bearing formation (104) and/or performing one or more reservoir simulations. For example, the reservoir simulator (160) may store well logs and data regarding core samples for performing simulations. A reservoir simulator may further analyze the well log data, the core sample data, seismic data, and/or other types of data to generate and/or update the one or more reservoir models. While the reservoir simulator (160) is shown at a well site, embodiments are contemplated where reservoir simulators are located away from well sites. In one or more embodiments, the reservoir simulator (160) may include a computer system that is similar to the computer system (800) described below with regard to FIGS. 7A and 7B and the accompanying description.

Keeping with reservoir simulators, a reservoir simulator may include functionality for solving well equations and reservoir equations separately, e.g., using Additive Schwartz methods. When the number of wells in a simulation is relatively small, computation time spent solving well equations may be a small fraction of the total computation time. However, in massive full-field simulations, where hundreds or thousands of wells are being simulated, the total computation time for solving well equations may increase considerably. This may be particularly true when a multi-segment well model is used as the number of unknown well parameters to be solved may be much larger than a conventional well model. As such, reservoir simulators may assign wells to computer processes in parallel computing tasks statically and/or dynamically. For example, at the beginning of a reservoir simulation, a well may be assigned to a single computer process that performs the computations necessary for this well. In one or more embodiments, placement of a well within a computer process may be independent of grid partitioning, e.g., whether the well is surrounded by fine-grid cells or coarsened grid blocks. During a simulation, a computer process may access both grid data for a reservoir model and well data. As such, well assignment may affect such parallel communication patterns and thereby may influence reservoir simulation performance.

In one or more embodiments, well assignment for parallel computer processes may include the case where a number of wells being simulated is greater than the number of computer processes involved in a reservoir simulation. Thus, multiple wells may be assigned to one computer process operating within a parallel processing stage. As wells may not need to be solved at all times during a reservoir simulation, e.g., only when the wells are producing or injecting, a situation may occur where one computer process is solving equations for multiple wells while a production well assigned to another computer process is inactive causing the computer process to be idle (i.e., waiting for the other computer processes to finish in the parallel processing stage).

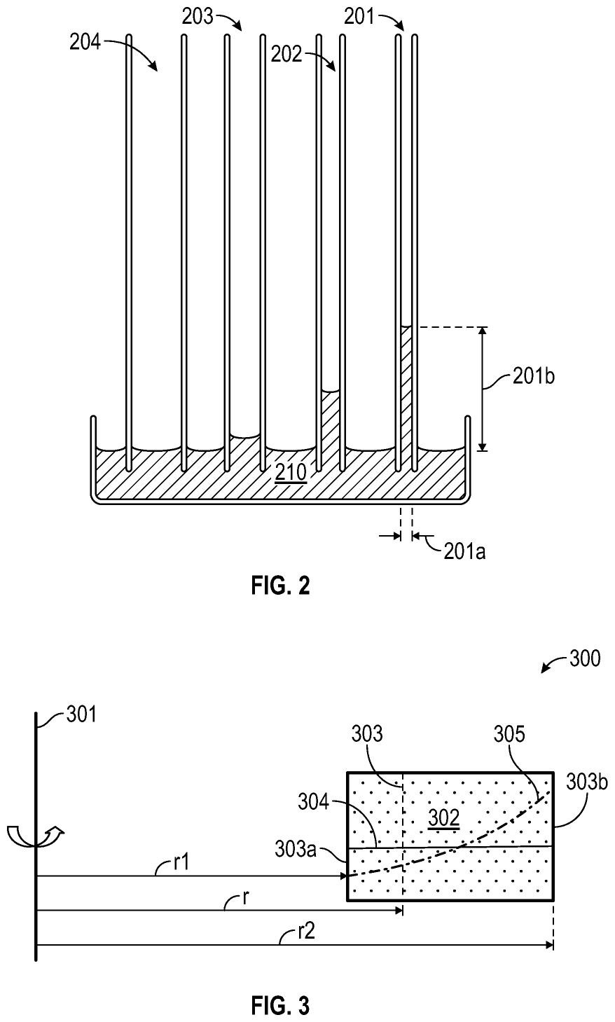

Turning to FIG. 2, FIG. 2 shows a schematic diagram in accordance with one or more embodiments. In one or more embodiments, one or more of the modules and/or elements shown in FIG. 2 may be omitted, repeated, and/or substituted. Accordingly, embodiments of the invention should not be considered limited to the specific arrangements of modules and/or elements shown in FIG. 2.

As shown in FIG. 2, FIG. 2 illustrates a capillary bundle model (200) of a porous media (e.g., a sedimentary rock in a reservoir). In particular, the capillary bundle model (200) approximates the pore spaces in the sedimentary rock (e.g., from a core sample of the reservoir) as aligned, separate capillary tubes (e.g., capillary tubes (201), (202), (203, (204)) in a fluid tank. The core sample saturated with a fluid (210) in the pore spaces is modeled as the fluid tank containing the fluid (210). Although four capillary tubes are shown in FIG. 2, the capillary bundle model (200) may include many more capillary tubes arranged in different configurations. Specifically, the capillary tube (201) represents a particular pore space where the capillary diameter (201a) represents a pore size and the capillary height (201b) represents a capillary pressure of the pore space in the core sample. In the capillary bundle model (200), the capillary pressure, reflected by the capillary height (201b), is related to the capillary diameter (201a) by the equation (Young-Laplace) below:

$${P}_{c} = ρ g h = \frac{2 σ cos θ}{R} \qquad Eq . ( 1 )$$

In the equation Eq. (1), Pc denotes the capillary pressure, σ denotes an interfacial tension, θ denotes a contact angle, R denotes the capillary radius or half of the capillary diameter, ρ denotes the density of the fluid (210), g denotes the gravitational constant, and h denotes the capillary height.

Based on the equation Eq. (1) above, the capillary bundle model (200) is used to model the pore size distribution in the core sample based on capillary pressure measurements of the core sample. The pore size distribution is a distribution function that specifies a tally of pore spaces with respect to the corresponding pore size over a range of pore sizes found in the core sample. For example, the tally may be expressed in an actual count, a percentage, a probability, or other type of measures. In the capillary bundle model (200), each of the capillary tubes (201), (202), (203), and (204) represents one pore and contributes one count to the pore size distribution.

Various methods may be used to physically measure the capillary pressure of the core sample. The methods include a porous plate method, a centrifuge method, and a mercury injection method. In each method, a core sample saturated with a particular fluid is invaded by another fluid under an applied external force to expel the particular fluid from the pore spaces. For example, the external force in the porous plate method is the gas pressure pressing the core sample against a porous plate where both the core sample and the porous plate are saturated with fluid. The external force in the centrifuge method is the centrifugal force created by spinning the saturated core sample around a rotation axis where the core sample is immersed in a different fluid. The external force in the mercury injection method is the pressure that forces the mercury to enter the saturated core sample. For each of these methods, at a hydrostatic equilibrium condition, the external force is counterbalanced by the capillary pressure in the core sample. For example, under the lowest level of the applied external force, the fluid may be expelled from larger pores represented by the capillary tube (204) but remains in the smaller pores represented by the capillary tubes (201), (202), and (203). Under an increased level of the applied external force, the fluid may be further expelled from pores represented by the capillary tube (203) but remains in the still smaller pores represented by the capillary tubes (201) and (202). The external force is applied with multiple incremented levels to record a relationship between the amount of fluid expelled from the core sample versus the applied external force. In the context that the external force is counterbalanced by the capillary pressure, the recorded relationship is referred to as the capillary pressure curve. At each hydrostatic equilibrium condition of the applied external force levels, the amount of the expelled fluid may be physically measured. Alternatively, a nuclear magnetic resonance (NMR) method is applied to the core sample to estimate the amount of fluid remaining in the core sample. The amount of the expelled fluid can be calculated by subtracting the remaining amount of the fluid from the initial amount of the fluid in the core sample.

In each of the methods described above, the measured capillary pressure curve is analyzed based on the capillary bundle model (e.g., capillary bundle model (200)) to generate the pore size distribution of the core sample. The type of pore size distribution, whether pore throat distribution, pore body distribution or a pore size distribution reflecting both pore throat and bore body, can depend on the particular method.

The concepts of pore body and pore throat may be better understood from the viewpoint of geometric methods with 3D pore space images and simulation. Examples of geometrical methods are thin section, SEM and microCT methods. Pore space may be defined based on the 3D microCT images and simulation. The pore, pore body, and pore throat are better understood with the help of digital rock physics (DRP) workflow based on 3D microscopic pore space images from a microCT scanner. The pore space images provide the direct observation of microscopic pore space. The complex 3D pore space can now be obtained by microCT scanner at sub-micron resolution. Some petrophysical properties such as porosity and permeability can be directly calculated, and single and two-phase flow can be directly simulated on the microscopic pore space. The microscopic space can be treated as a whole. However, direct simulation is still very computationally expensive. The pore network model is widely used for simulation without high computation demand.

Like the pore network model based on the 2D images from the thin section and scanning electron microscope (SEM), pore, pore body, and pore throat are introduced in the 3D pore network model extracted from 3D microCT images. The pore space is divided into large pores (body) connected by small pore throats, which is a good simplification of sandstone's relatively simple inter-particle pore space. In the pore network model, the pore body is represented by balls, and sticks represent pore throats. Natural outcomes are the pore body and throat size distribution by numbers. The pore body size distribution may be obtained by volume as well. These direct geometrical measurements may not be the same as the pore size distributions by other methods, and their application to the formation evaluation needs to be studied. The pore size distribution by other methods, for example mercury injection method (MICP), can be obtained by simulating the direct geometrical measurement process.

Pore size distribution may be obtained by an MICP method. When the mercury is injected into rocks under pressure, the entry of mercury into the pore space is controlled by the pore restriction or throat, not by the pore body. The pressure and injected mercury volume (or saturation) are recorded during measurements. Pore throat size distribution can be derived from the Equation (2) both from capillary pressure models and raw capillary pressure and saturation data points:

$$f ( {r}_{t} ) = \frac{d S}{d ( log ( {r}_{t} ) )} \qquad ( 2 )$$

where rₜ can be obtained by using Equation (1) to determine rₜ from P_{c} where R=rₜ in equation (1). The pore size distribution obtained by this method is the pore throat size, and the accessible volume is controlled by the throat size. This pore throat size distribution is different from both the pore body distribution and from the throat size distribution by numbers or volume from the imaging methods discussed above. MICP pore size distribution can be obtained by direct simulation and pore network modeling of mercury intrusion on digital rocks.

Pore size distribution may be obtained by an NRM method. Nuclear magnetic resonance (NMR) has become a common method both in the laboratory for rock property measurements and in well logging for formation evaluation. It is non-destructive and can be easily performed on 100% brine saturated rock samples and integrated into other experimental procedures. The transverse relaxation time (T₂) distribution at 100% water saturation is known to be associated with pore size distribution:

$$\frac{1}{{T}_{2}} = \frac{1}{{T}_{2 b u l k}} + {ρ}_{2} \frac{S}{V} + \frac{{( γ G T E )}^{2} D}{12} \approx {ρ}_{2} \frac{S}{V} = {ρ}_{2} \frac{3}{{r}_{b}} \qquad ( 3 )$$

where T2 is the transverse relaxation time, ρ₂ is the surface relaxivity, S is the surface area of pore space, V is the pore volume, T2bulk is bulk water relaxation time, γ is proton gyromagnetic ratio, G is the gradient strength, TE is the time of echo, and D is the diffusion coefficient. The bulk and diffusion terms can often be ignored in the laboratory, and the last step assumes that the pore shape is spherical. As can be seen, the T2 is proportional to both pore body and throat sizes. The T2 distribution can be expressed as incremental or cumulative volume versus T2. T2 distribution can be obtained on a digital rock by random walk method to simulate the relaxation process.

The T2 distributions indicate both pore body and pore throat sizes, but they mainly reflect pore body size distributions like pore body size distribution by volume from images because of their large volume compared to pore throats. The pore (throat) size distributions by MICP indicate that the accessible volume fraction is controlled by the size of a specific pore throat. Due to the irregular microscopic pores and their complex connectivity, one pore throat size controls a range of pore body sizes, and different pore throat sizes can control one pore body size. When NMR and MICP distributions are plotted together, the shapes and ranges of distributions do not usually match each other unless for regular pore spaces.

Despite promising results for some rock samples, room remains for improved overlap between NMR-based pore size distributions and MICP pore size distributions. One reason for potentially limited overlap is sample heterogeneity. MICP and NMR measurements are conducted on different rock samples and MICP samples are relatively smaller, which is affected more by heterogeneity. Another reason for potentially limited overlap is that the MICP and NRM measurements reveal different pore characteristics. In particular, the MICP pore size distribution reflects pore throat sizes. In contrast, NMR T2 distributions reflect both pore body and throat sizes, although they mainly reflect pore body sizes.

In the present method, a conversion procedure connects the MICP pore throat size directly to the T2 distribution of the accessible volume. The new method takes advantage of NMR saturation profile measurements and spatial T2 distribution measurements during a desaturation of 100% water-saturated sample by centrifuge. Water/air capillary pressure can be obtained from saturation profiles, and pore throat size can be derived from capillary pressure. The T2 distribution of accessible volume can be obtained by subtraction of spatial T2 distribution. The pore throat size and T2 distribution correspondence can establish on distinguishable intervals, and a smooth conversion curve can be built by interpolation.

Turning to FIG. 3, FIG. 3 shows a schematic diagram in accordance with one or more embodiments. In one or more embodiments, one or more of the modules and/or elements shown in FIG. 3 may be omitted, repeated, and/or substituted. Accordingly, embodiments of the invention should not be considered limited to the specific arrangements of modules and/or elements shown in FIG. 3.

As shown in FIG. 3, FIG. 3 illustrates a centrifuge (300), which is a piece of equipment that secures the core (302) in a sample holder where the sample holder rotates around the rotation axis (301) at a controlled rotational speed. The core (302) is an example of the core sample described in reference to FIGS. 1 and 2 above. In the centrifuge (300), the distance from the rotation axis (301) to the nearest surface of the core (302) (i.e., the inlet face (303a)) is denoted as r1, and the distance from the rotation axis (301) to the farthest surface of the core (302) (i.e., the outlet face (303b)) is denoted as r2. In one example configuration, the length of the core (302) (i.e., difference between r2 and r1) is substantially less than (e.g., <10%) the distance r2 or r1. For the purpose of recording the capillary pressure curve, the centrifugal force at a particular rotational speed is approximately the same throughout the core (302). Through multiple rotation sessions of the centrifuge (300), the core (302) is rotated at successively incremented rotational speeds such that multiple levels of centrifugal force are successively applied to the core (302). Subsequent to each rotation session, the average saturation (304) is measured as an indication of the amount of fluid remaining in the core (302). In such configuration, the capillary pressure curve is recorded based on multiple successive rotation sessions of the centrifuge (300) at multiple rotational speeds.

In another example configuration, the length of the core (302) (i.e., difference between r2 and r1) is a large portion (e.g., >10%) of the distance r2 or r1. For the purpose of recording the capillary pressure curve, the centrifugal force increases from the inlet face (303a) to the outlet face (303b). Within a slice (e.g., slice (303)) of the core (302), the centrifugal force is approximated as a constant. A slice is a cross-section of the core (302) having a thickness substantially smaller than (e.g., <10%) the distance r2 or r1. For example, the centrifugal force exerted to the slice (303) is related to the rotational speed of the centrifuge (300) by the equation below:

$${F}_{c} = m {ω}^{2} r \qquad Eq . ( 2 )$$

In the equation Eq. (2), F_{c} denotes the centrifugal force, m denotes the mass of the slice (303), ω denotes the angular rotational speed, and r denotes the distance of the slice (303) from the rotational axis (301). According to the equation Eq (2), increasing levels of centrifugal force are applied to successive slices of the core (302). Subsequent to a single rotation session, the saturation profile (305) is measured as an indication of the amount of fluid remaining in the core (302). The saturation profile is a set of recorded data that specifies a saturation measure for each slice in the core sample. Because a range of saturation measurements are recorded in the saturation profile (305) corresponding to successively increasing centrifugal force levels, the capillary pressure curve is recorded based on a single rotation session of the centrifuge (300) at a single rotational speed.

The capillary pressure from NMR saturation profiles concerns the air/water in the present method. NMR capillary pressure can be obtained from the NMR saturation profile and capillary pressure from centrifugal forces. Two or more saturation profiles are obtained from low centrifuge speeds to high centrifuge speeds. A saturation profile or gradient forms along the core length because of the difference in saturation profiles at different spinning speeds. The core end near the axis has the lowest water saturation, while the other far end has the highest saturation.

The capillary pressure can be calculated directly from a distance (rᵢ) between the saturation at slice i and the centrifugal center along the core length (at distance r_{c}).

$${P}_{c} ( {r}_{i} ) = \frac{1}{2} Δ ρ {ω}^{2} ( {r}_{c} - {r}_{i} ) \qquad Eq . ( 3 )$$

The invasion of air into 100% brine saturated rock sample is the same process as the invasion process of mercury into the rock samples. Equation (1) is used to calculate the pore throat size, where R=rₜᵢ and P_{c}=P_{c}(rᵢ), a function of rᵢ. That is,

$${r}_{t i} = \frac{2 σ cos θ}{{P}_{c} ( {r}_{i} )} \qquad Eq . ( 4 )$$

This differs from mercury invasion. For mercury invasion, the capillary pressure is uniform along the sample length, while the capillary pressure from centrifugal force depends on the distance from the centrifugal axis.

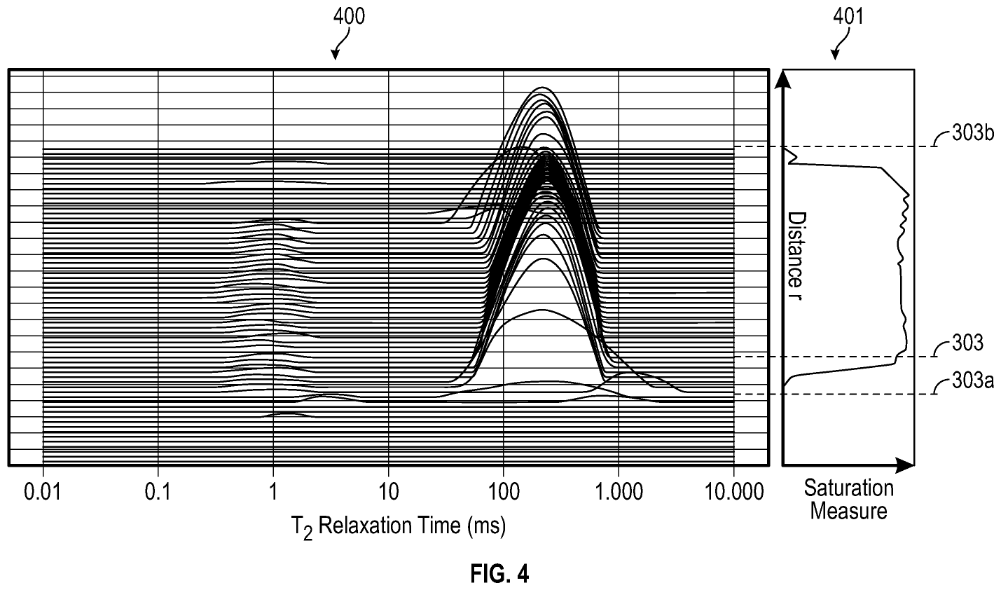

Turning to FIG. 4, FIG. 4 illustrates a spatial T2 distribution (400) and a saturation profile (401), e.g., of the core (302) that are generated using the centrifuge (300) depicted in FIG. 3 above. The saturation profile (401) is a plot of saturation measures as a function of distance from rotation axis (301). The saturation profile (401) includes a range from the inlet face (303a) to the outlet face (303b) through the length of the core (302). The spatial T2 distribution (400) is the collection of T2 distributions that are individually inverted from the NMR measurements of successive thin slices of the core (302). The saturation measure is the integral of T2 amplitudes in the T2 distribution of each slice.

The saturation is determined for each thin slice depending on the NMR measurement parameters. The thickness of the slice is usually around one millimeter. The center of i−1 slice from the axis corresponds to pore throat size rₜᵢ₋₁ while i slice from the axis rₜᵢ. The accessible volume difference controlled by rₜᵢ₋₁ and rₜᵢ is ΔS=Sᵢ−Sᵢ₋₁. The T2 distribution of this slice can be determined. Thus, the direct connection can be established between average pore throat size and the T2 distribution.

T2 distribution may be commonly performed on the whole rock sample. If a relaxometer is equipped with a gradient coil spatial T2, or the T2 distribution of each thin slice along the core length can be obtained like a saturation profile. Similar to the correspondence between pore throat size and saturation, the T2 distribution of accessible volume is the subtraction of slice i−1 from slice i. It is better for the subtraction to be performed on the relaxation curves instead of the T2 distributions since the latter may generate negative volume. The T2 time, T₂ᵢ, can be taken at the peak because the subtracted distribution is close to symmetrical. The direct connection between average pore throat size

$$\frac{{r}_{t i} - {r}_{t i - 1}}{2}$$

and its T₂ᵢ is established. The procedure can be conducted on other slices and a series of pore throat sizes or T₂ᵢ versus accessible volume can be obtained, which is the pore throat size distribution by definition.

It is worth noting that the incremental volumes of NMR T2 distribution discussed above are different from the accessible volumes at the same T2 by subtraction discussed above. The incremental volume of NMR T2 distribution corresponds to one pore body size, while the accessible volume contains most of the incremental volumes with additional pore body sizes above and below the size as well as long as it can be accessed by the pore throat. The T2 values of accessible volumes are the average of all accessible volumes, and it applies to all T2 values. Thus, the incremental volume can be used as accessible volume because they are very close. This approximation is used due to the limited number of slices of spatial T2. Due to the heterogeneity of the core samples, the T2 and saturation differences between consecutive slices of spatial T2 may not monotonically change with a significant difference at a small thickness of the slices. It limits the number of data points of the curve less than the total data points of more than 100 for both MICP (e.g., 118 logarithmically spaced data points from around 0.003μm to above 100μm) and NMR (e.g., 121 logarithmically spaced data points from 0.01 ms to 10000 ms). The NMR T2 distribution will be converted with the scaling factors interpolated from the above data points from each slice.

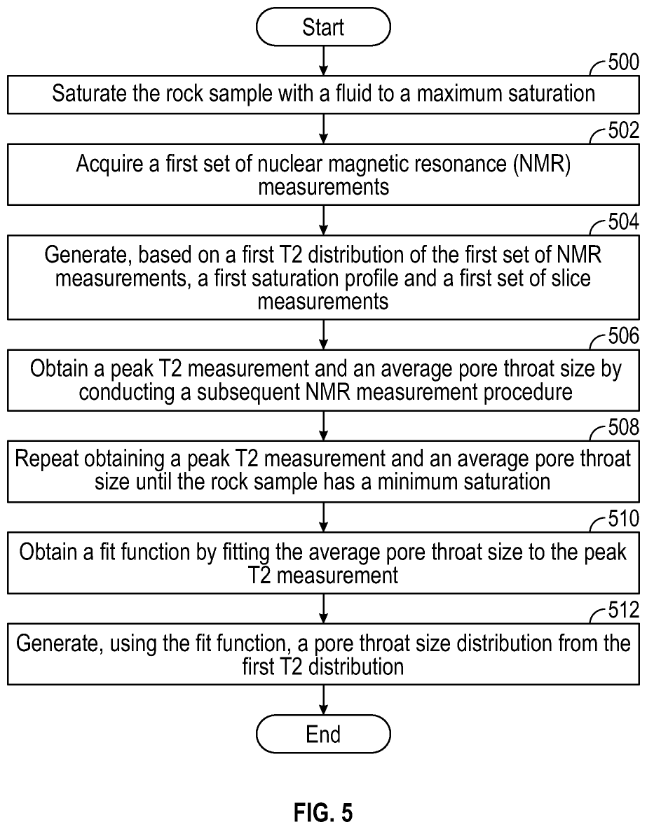

Turning to FIG. 5, FIG. 5 shows a flowchart in accordance with one or more embodiments. Specifically, FIG. 5 describes a method for determining the pore size distribution of reservoir rocks having rough pore surfaces. One or more blocks in FIG. 5 may be performed using one or more components (e.g., reservoir simulator (160), capillary bundle model (200), centrifuge (300), saturation profile (401)) as described in FIGS. 1, 2, 3, and 4. While the various blocks in FIG. 5 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

Initially in Block 500, a rock sample is saturated with a fluid. The rock sample may be a core sample obtained from the reservoir by drilling. The rock sample represents characteristics of the reservoir rocks. The fluid may be a brine solution. The rock sample may be saturation to a maximum saturation. The maximum saturation may be about 100%.

In Block 502, a first set of nuclear magnetic resonance (NMR) measurements of the rock sample is acquired.

In Block 504, a first saturation profile and a first set of slice measurements are generated based on a T2 distribution of the first set of NMR measurements. The T2 distribution is generated by inversion of the first set of NMR measurements. The first saturation measure represents an initial amount of the fluid stored in the rock sample that is measured as a percentage, a ratio, a value with a physical unit, or other suitable formats. In one or more embodiments, the first saturation measure is generated by computing an integral of the first T2 distribution with respect to the transverse relaxation time. Each slice measure may be a spatial T2 distribution. Alternatively, each slice measure may be a time-domain relaxation curve. The first set of slice measures may be homogeneous.

In Block 506, a peak T2 measurement and an average pore throat size are obtained by conducting a subsequent measurement procedure. Conducting the subsequent measurement procedure may include applying, subsequent to acquiring the first set of NMR measurements, an external force to the rock sample to reduce the saturation of the rock sample. Conducting the subsequent measurement procedure may further include acquiring, after applying the external force, a subsequent set of NMR measurements of the rock sample. Conducting the subsequent measurement procedure may further include generating based on a subsequent T2 distribution of the subsequent set of NMR measurements, a subsequent saturation profile, a subsequent set of slice measures, and an average pore throat size measurement. Conducting the subsequent measurement procedure may further include obtaining a peak T2 measurement by subtracting the subsequent set of slice measures from the initial set of slice measures. Each slice measure may be a spatial T2 distribution. Alternatively, each slice measure may be a time-domain relaxation curve. The subsequent set of slice measures may be homogeneous. The set of subsequent slice measures may span a saturation interval. The saturation interval may have a width of from about 5% to about 15%. The external force have the form of a centrifugal force.

In Block 508, obtaining a peak T2 measurement and an average pore throat size is repeated until the rock sample has a minimum saturation. The minimum saturation may be an irreducible saturation. The irreducible saturation may be at a highest possible speed.

In Block 510, a fit function is obtained by fitting the average pore throat size to the peak T2 measurement. The fitting may include plotting the average pore throat size vs. the peak T2. The points in the plot may be fit with the fit function. The fit function may be a spline function.

In Block 512, a pore throat size distribution may be generated, using the fit function, from the first T2 distribution. The T2 of the x-axis of the T2 distribution at the maximum saturation (Sw) may be converting to pore throat sizes according to the fit function from Block 510. Thus, the T2 distribution of the first set of NMR measurements may be converted to the pore throat size distribution.

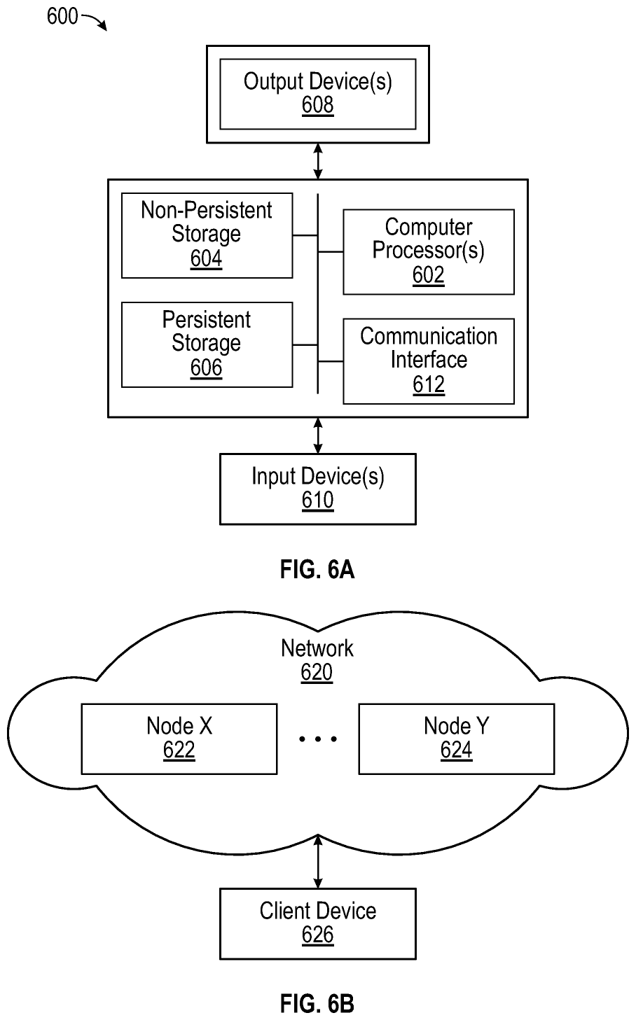

Embodiments may be implemented on a computing system. A suitable combination of mobile, desktop, server, router, switch, embedded device, or other types of hardware may be used. For example, as shown in FIG. 6A, the computing system (600) may include one or more computer processors (602), non-persistent storage (604) (e.g., volatile memory, such as random access memory (RAM), cache memory), persistent storage (606) (e.g., a hard disk, an optical drive such as a compact disk (CD) drive or digital versatile disk (DVD) drive, a flash memory, etc.), a communication interface (612) (e.g., Bluetooth interface, infrared interface, network interface, optical interface, etc.), and numerous other elements and functionalities.

The computer processor(s) (602) may be an integrated circuit for processing instructions. For example, the computer processor(s) may be one or more cores or micro-cores of a processor. The computing system (600) may also include one or more input devices (610), such as a touchscreen, keyboard, mouse, microphone, touchpad, electronic pen, or any other type of input device.

The communication interface (612) may include an integrated circuit for connecting the computing system (600) to a network (not shown) (e.g., a local area network (LAN), a wide area network (WAN) such as the Internet, mobile network, or any other type of network) and/or to another device, such as another computing device.

Further, the computing system (600) may include one or more output devices (808), such as a screen (e.g., a liquid crystal display (LCD), a plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (602), non-persistent storage (604), and persistent storage (606). Many different types of computing systems exist, and the aforementioned input and output device(s) may take other forms.

Software instructions in the form of computer readable program code to perform embodiments of the disclosure may be stored, in whole or in part, temporarily or permanently, on a non-transitory computer readable medium such as a CD, DVD, storage device, a diskette, a tape, flash memory, physical memory, or any other computer readable storage medium. Specifically, the software instructions may correspond to computer readable program code that, when executed by a processor(s), is configured to perform one or more embodiments of the disclosure.

The computing system (600) in FIG. 6A may be connected to or be a part of a network. For example, as shown in FIG. 6B, the network (620) may include multiple nodes (e.g., node X (622), node Y (624)). Each node may correspond to a computing system, such as the computing system shown in FIG. 6A, or a group of nodes combined may correspond to the computing system shown in FIG. 6A. By way of an example, embodiments of the disclosure may be implemented on a node of a distributed system that is connected to other nodes. By way of another example, embodiments of the disclosure may be implemented on a distributed computing system having multiple nodes, where each portion of the disclosure may be located on a different node within the distributed computing system. Further, one or more elements of the aforementioned computing system (600) may be located at a remote location and connected to the other elements over a network.

Although not shown in FIG. 6B, the node may correspond to a blade in a server chassis that is connected to other nodes via a backplane. By way of another example, the node may correspond to a server in a data center. By way of another example, the node may correspond to a computer processor or micro-core of a computer processor with shared memory and/or resources.

The nodes (e.g., node X (622), node Y (624)) in the network (620) may be configured to provide services for a client device (626). For example, the nodes may be part of a cloud computing system. The nodes may include functionality to receive requests from the client device (626) and transmit responses to the client device (626). The client device (626) may be a computing system, such as the computing system shown in FIG. 6A. Further, the client device (626) may include and/or perform all or a portion of one or more embodiments of the disclosure.

The computing system or group of computing systems described in FIGS. 6A and 6B may include functionality to perform a variety of operations disclosed herein. For example, the computing system(s) may perform communication between processes on the same or different systems. A variety of mechanisms, employing some form of active or passive communication, may facilitate the exchange of data between processes on the same device. Examples representative of these inter-process communications include, but are not limited to, the implementation of a file, a signal, a socket, a message queue, a pipeline, a semaphore, shared memory, message passing, and a memory-mapped file. Further details pertaining to a couple of these non-limiting examples are provided below.

Based on the client-server networking model, sockets may serve as interfaces or communication channel end-points enabling bidirectional data transfer between processes on the same device. Foremost, following the client-server networking model, a server process (e.g., a process that provides data) may create a first socket object. Next, the server process binds the first socket object, thereby associating the first socket object with a unique name and/or address. After creating and binding the first socket object, the server process then waits and listens for incoming connection requests from one or more client processes (e.g., processes that seek data). At this point, when a client process wishes to obtain data from a server process, the client process starts by creating a second socket object. The client process then proceeds to generate a connection request that includes at least the second socket object and the unique name and/or address associated with the first socket object. The client process then transmits the connection request to the server process. Depending on availability, the server process may accept the connection request, establishing a communication channel with the client process, or the server process, busy in handling other operations, may queue the connection request in a buffer until the server process is ready. An established connection informs the client process that communications may commence. In response, the client process may generate a data request specifying the data that the client process wishes to obtain. The data request is subsequently transmitted to the server process. Upon receiving the data request, the server process analyzes the request and gathers the requested data. Finally, the server process then generates a reply including at least the requested data and transmits the reply to the client process. The data may be transferred, more commonly, as datagrams or a stream of characters (e.g., bytes).

Shared memory refers to the allocation of virtual memory space in order to substantiate a mechanism for which data may be communicated and/or accessed by multiple processes. In implementing shared memory, an initializing process first creates a shareable segment in persistent or non-persistent storage. Post creation, the initializing process then mounts the shareable segment, subsequently mapping the shareable segment into the address space associated with the initializing process. Following the mounting, the initializing process proceeds to identify and grant access permission to one or more authorized processes that may also write and read data to and from the shareable segment. Changes made to the data in the shareable segment by one process may immediately affect other processes, which are also linked to the shareable segment. Further, when one of the authorized processes accesses the shareable segment, the shareable segment maps to the address space of that authorized process. Often, one authorized process may mount the shareable segment, other than the initializing process, at any given time.

Other techniques may be used to share data, such as the various data described in the present application, between processes without departing from the scope of the disclosure. The processes may be part of the same or different application and may execute on the same or different computing system.

Rather than or in addition to sharing data between processes, the computing system performing one or more embodiments of the disclosure may include functionality to receive data from a user. For example, in one or more embodiments, a user may submit data via a graphical user interface (GUI) on the user device. Data may be submitted via the graphical user interface by a user selecting one or more graphical user interface widgets or inserting text and other data into graphical user interface widgets using a touchpad, a keyboard, a mouse, or any other input device. In response to selecting a particular item, information regarding the particular item may be obtained from persistent or non-persistent storage by the computer processor. Upon selection of the item by the user, the contents of the obtained data regarding the particular item may be displayed on the user device in response to the user's selection.

By way of another example, a request to obtain data regarding the particular item may be sent to a server operatively connected to the user device through a network. For example, the user may select a uniform resource locator (URL) link within a web client of the user device, thereby initiating a Hypertext Transfer Protocol (HTTP) or other protocol request being sent to the network host associated with the URL. In response to the request, the server may extract the data regarding the particular selected item and send the data to the device that initiated the request. Once the user device has received the data regarding the particular item, the contents of the received data regarding the particular item may be displayed on the user device in response to the user's selection. Further to the above example, the data received from the server after selecting the URL link may provide a web page in Hyper Text Markup Language (HTML) that may be rendered by the web client and displayed on the user device.

Once data is obtained, such as by using techniques described above or from storage, the computing system, in performing one or more embodiments of the disclosure, may extract one or more data items from the obtained data. For example, the extraction may be performed as follows by the computing system (600) in FIG. 6A. First, the organizing pattern (e.g., grammar, schema, layout) of the data is determined, which may be based on one or more of the following: position (e.g., bit or column position, Nth token in a data stream, etc.), attribute (where the attribute is associated with one or more values), or a hierarchical/tree structure (consisting of layers of nodes at different levels of detail—such as in nested packet headers or nested document sections). Then, the raw, unprocessed stream of data symbols is parsed, in the context of the organizing pattern, into a stream (or layered structure) of tokens (where each token may have an associated token “type”).

Next, extraction criteria are used to extract one or more data items from the token stream or structure, where the extraction criteria are processed according to the organizing pattern to extract one or more tokens (or nodes from a layered structure). For position-based data, the token(s) at the position(s) identified by the extraction criteria are extracted. For attribute/value-based data, the token(s) and/or node(s) associated with the attribute(s) satisfying the extraction criteria are extracted. For hierarchical/layered data, the token(s) associated with the node(s) matching the extraction criteria are extracted. The extraction criteria may be as simple as an identifier string or may be a query presented to a structured data repository (where the data repository may be organized according to a database schema or data format, such as XML).

The extracted data may be used for further processing by the computing system. For example, the computing system of FIG. 7A, while performing one or more embodiments of the disclosure, may perform data comparison. Data comparison may be used to compare two or more data values (e.g., A, B). For example, one or more embodiments may determine whether A>B, A=B, A!=B, A<B, etc. The comparison may be performed by submitting A, B, and an opcode specifying an operation related to the comparison into an arithmetic logic unit (ALU) (i.e., circuitry that performs arithmetic and/or bitwise logical operations on the two data values). The ALU outputs the numerical result of the operation and/or one or more status flags related to the numerical result. For example, the status flags may indicate whether the numerical result is a positive number, a negative number, zero, etc. By selecting the proper opcode and then reading the numerical results and/or status flags, the comparison may be executed. For example, in order to determine if A>B, B may be subtracted from A (i.e., A−B), and the status flags may be read to determine if the result is positive (i.e., if A>B, then A−B>0). In one or more embodiments, B may be considered a threshold, and A is deemed to satisfy the threshold if A=B or if A>B, as determined using the ALU. In one or more embodiments of the disclosure, A and B may be vectors, and comparing A with B includes comparing the first element of vector A with the first element of vector B, the second element of vector A with the second element of vector B, etc. In one or more embodiments, if A and B are strings, the binary values of the strings may be compared.

The computing system in FIG. 6A may implement and/or be connected to a data repository. For example, one type of data repository is a database. A database is a collection of information configured for ease of data retrieval, modification, re-organization, and deletion. Database Management System (DBMS) is a software application that provides an interface for users to define, create, query, update, or administer databases.

The user, or software application, may submit a statement or query into the DBMS. Then the DBMS interprets the statement. The statement may be a select statement to request information, update statement, create statement, delete statement, etc. Moreover, the statement may include parameters that specify data, or data container (database, table, record, column, view, etc.), identifier(s), conditions (comparison operators), functions (e.g. join, full join, count, average, etc.), sort (e.g. ascending, descending), or others. The DBMS may execute the statement. For example, the DBMS may access a memory buffer, a reference or index a file for read, write, deletion, or any combination thereof, for responding to the statement. The DBMS may load the data from persistent or non- persistent storage and perform computations to respond to the query. The DBMS may return the result(s) to the user or software application.

The computing system of FIG. 6A may include functionality to present raw and/or processed data, such as results of comparisons and other processing. For example, presenting data may be accomplished through various presenting methods. Specifically, data may be presented through a user interface provided by a computing device. The user interface may include a GUI that displays information on a display device, such as a computer monitor or a touchscreen on a handheld computer device. The GUI may include various GUI widgets that organize what data is shown as well as how data is presented to a user. Furthermore, the GUI may present data directly to the user, e.g., data presented as actual data values through text, or rendered by the computing device into a visual representation of the data, such as through visualizing a data model.

For example, a GUI may first obtain a notification from a software application requesting that a particular data object be presented within the GUI. Next, the GUI may determine a data object type associated with the particular data object, e.g., by obtaining data from a data attribute within the data object that identifies the data object type. Then, the GUI may determine any rules designated for displaying that data object type, e.g., rules specified by a software framework for a data object class or according to any local parameters defined by the GUI for presenting that data object type. Finally, the GUI may obtain data values from the particular data object and render a visual representation of the data values within a display device according to the designated rules for that data object type.

Data may also be presented through various audio methods. In particular, data may be rendered into an audio format and presented as sound through one or more speakers operably connected to a computing device.

Data may also be presented to a user through haptic methods. For example, haptic methods may include vibrations or other physical signals generated by the computing system. For example, data may be presented to a user using a vibration generated by a handheld computer device with a predefined duration and intensity of the vibration to communicate the data.

The above description of functions presents only a few examples of functions performed by the computing system of FIG. 6A and the nodes and/or client device in FIG. 6B. Other functions may be performed using one or more embodiments of the disclosure.

### EXAMPLES

### Example 1—Workflow

This example provides an exemplary workflow for obtaining a pore throat size distribution from NMR measurements using typical core samples is described below. The workflow includes experimental and data analysis procedures.

The experimental procedure proceeds as follows. At stage 1, select dry core samples of about 5 cm (2 inches) to 7.5 cm (3 inches) long. At stage 2, saturate the sample with water or brine. At stage 3, perform T2 distribution, saturation profile and spatial T2 measurements. The total slice number should be in the range of 10 (about 5 mm slice thickness) to 50 (about 1 mm slice thickness) for a typical 5 cm long core sample to ensure the clear saturation gradient. At stage 4, select the samples with less heterogeneity based on saturation profiles and spatial T2 measured from performing the saturation profile, and spatial T2 measurements at stage 3. At stage 5, select 3 or more spinning speeds based on porosity and permeability. At stage 6, spin the samples in the centrifuge at the 1^{st} selected speed, then conduct T2 distribution, saturation profile, and spatial T2 measurements. At stage 7, repeat stage 6 until irreducible saturation (S_{wr}) is reached at a highest possible speed. The highest speed depends on the sample integrity and the sample gas permeability. Optionally, at stage 8, clean the sample or re-saturate the sample for other tests.

The data analysis procedure proceeds as follows. At stage 9, pick a group of slices at and near 100% saturation next to the front of the air invasion as a 1^{st} group of slices. At stage 10, pick a 2^{nd} group of slices at the saturation of 5 to 15% lower. At stage 11, calculate an average pore throat size based on Equation (3) and Equation (4). At stage 12, conduct time-domain subtraction of the 2^{nd} group of slices from the 1^{st} group of slices and obtain a peak T2. At stage 13, repeat stages 10, 11, 12 until approaching S_{wr}. At stage 14, plot average pore throat size vs. peak T2 and fit the points with a spline function. At stage 15, convert the T2 of the x-axis of the T2 distribution at 100% Sw to pore throat sizes according to the spline function from stage 14, thus converting T2 distribution to pore throat size distribution.

### Example 2

This example illustrates the application of the workflow of Example 1 to obtain a pore throat distribution from NMR measurements.

After each centrifuge step, the sample is taken out for the NMR measurements (Question 8-10). The measurements, T2 distribution, the water saturation profile for NMR P_{c}, and the spatial T2 are performed. The saturation profiles shown in FIG. 7 are similar in type to saturation profile 305. Air invades from the right end. The NMR P_{c} shown in FIG. 8 can be derived for the series of the saturation profiles using Equation (3), and the pore throat size distribution obtained from the P_{c} using Equation (4).

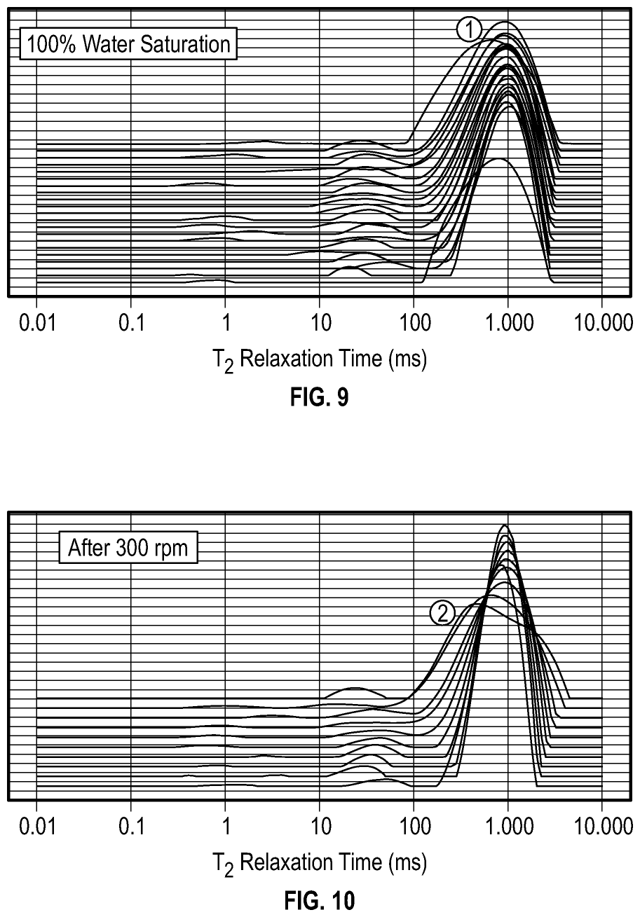

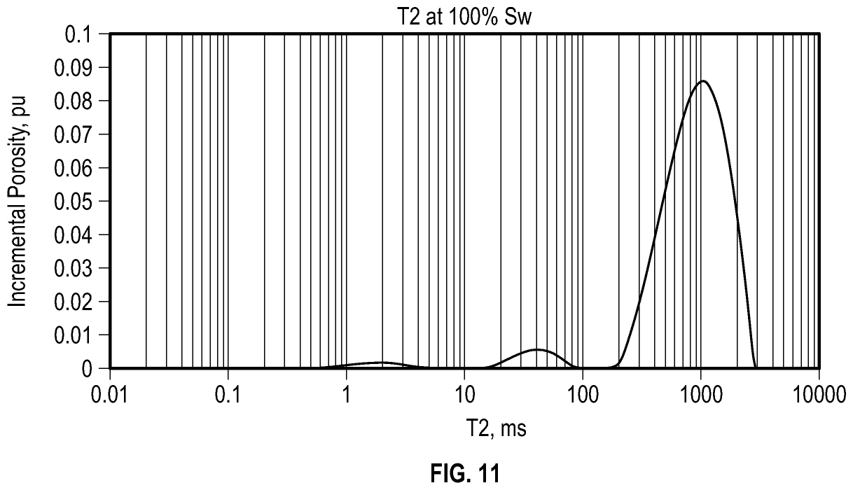

The stack plot spatial T2 at 100% saturation is shown in FIG. 8 and the stack plot spatial T2 at 300 rpm is shown in FIG. 9. The area under each curve equals the saturation value of the saturation profile at the same position. The slice number of spatial T2 and saturation profile could be different due to the different measurements, however they can be lined with the same position along the core length. For example, the marked numbers (1, 2, 3 . . . ) are at the same positions on different graphs.

The 1^{st} slice or group of slices marked as 1 is shown at one end on above saturation and spatial T2 graph (Question 1). Even though the sample should be very homogeneous shown in uniform saturation profile at 100% Sw and almost identical T2 distributions it is better to keep consecutive selected slices adjacent to avoid any heterogeneity along the sample.

The 2^{nd} group of slices is selected using the saturation interval of 5 to 15%, shown in the 2^{nd} spatial T2 graph, saturation profile and NMR P_{c} graph. The same saturation can be found on more than one profiles. It is better to select the one closer to the last selection.

The capillary pressure and pore throat size can be obtained from the NMR P_{c} graph based on the saturation value using Equation (3) and Equation (4).

As can be seen from the spatial T2, the area under the curves become smaller compared to the previous centrifuge spinning or 100% Sw. If the curve shapes are very similar the subtraction can be performed simply on the distributions. If the curve shape are significantly different the subtraction can be formed in their time-domain relaxation curves first.

The irreducible water saturation is the saturation after centrifuge spinning at the highest speed (e.g. 4500 rpm) and the saturation profile should be relatively flat. The next group of slices may be selected based on the saturation interval again until approaching the irreducible water saturation.

The link between the pore throat sizes and the average resultant T2 distributions from subtraction is established. The multiple data points are fitted using spline function for later application.

An example of T2 distribution at 100% saturation is shown in FIG. 10. It is the same as the sum of all spatial T2 distributions measured quickly. The present method obtains the function of the pore throat size and T2 distribution from the direct measurement of the same pore space.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method for determining a pore throat size distribution in a rock sample, the method comprising:
saturating the rock sample with a fluid to a maximum saturation;
acquiring a first set of nuclear magnetic resonance (NMR) measurements of the rock sample;
generating based on a first T2 distribution of the first set of NMR measurements, a first saturation profile and a first set of slice measurements;
obtaining a peak T2 measurement and an average pore throat size measurement by conducting a subsequent NMR measurement procedure;
repeating obtaining a peak T2 measurement until the rock sample has a minimum saturation;
obtaining a fit function by fitting the average pore throat size measurements to the peak T2 measurements; and
generating, using the fit function, a pore throat size distribution from the first T2 distribution.

2. The method according to claim 1, wherein the maximum saturation is about 100%.

3. The method according to claim 1, wherein the minimum saturation is an irreducible saturation.

4. The method according to claim 1, wherein each slice measure is a spatial T2 distribution.

5. The method according to claim 1, wherein each slice measure is a time-domain relaxation curve.

6. The method according to claim 1, wherein the first set of slice measures is homogeneous.

7. The method according to claim 1, wherein conducting a subsequent measurement procedure comprises:
applying, subsequent to acquiring the first set of NMR measurements, an external force to the rock sample to reduce the saturation of the rock sample;
acquiring, after applying the external force, a subsequent set of NMR measurements of the rock sample;
generating based on a subsequent T2 distribution of the subsequent set of NMR measurements, a subsequent saturation profile, a subsequent set of slice measures, and an average pore throat size measurement; and
obtaining a peak T2 measurement by subtracting the subsequent set of slice measures from the initial set of slice measures.

8. The method according to claim 7, wherein the set of subsequent slice measures comprises a saturation interval.

9. The method according to claim 8, wherein the saturation interval has a width of from about 5% to about 15%.

10. The method according to claim 7, wherein the external force comprises a centrifugal force.

11. A computer system for determining a pore size distribution in a rock sample, comprising:
a processor; and
a memory coupled to the processor, the memory storing instructions, when executed, comprising functionality for:
acquiring a first set of nuclear magnetic resonance (NMR) measurements of the rock sample, wherein the rock sample is saturated with a fluid to a maximum saturation;
generating based on a first T2 distribution of the first set of NMR measurements, a first saturation profile, and a first set of spatial T2 distributions;
obtaining a peak T2 measurement by conducting a subsequent measurement procedure:
repeating conducting the subsequent procedure until saturation of the rock sample has a minimum saturation;
obtaining a fit function by fitting the average pore throat size measurements to the peak T2 measurements; and
generating, using the fit function, a pore throat size distribution from the first T2 distribution.

12. The system according to claim 11, wherein the maximum saturation is about 100%.

13. The system according to claim 11, wherein the minimum saturation is an irreducible saturation.

14. The system according to claim 11, wherein each slice measure is a spatial T2 distribution.

15. The system according to claim 11, wherein each slice measure is a time-domain relaxation curve.

16. The system according to claim 11, wherein the first set of slice measures is homogeneous.

17. The system according to claim 11, wherein conducting the subsequent procedure comprises:
applying, subsequent to acquiring the first set of NMR measurements, an external force to the rock sample to reduce the saturation of the rock sample;
acquiring, after applying the external force, a subsequent set of NMR measurements of the rock sample, wherein the rock sample has been exposed, subsequent to acquiring the first set of NMR measurements, to an external force to the rock sample to reduce the saturation of the rock sample;
generating based on a subsequent T2 distribution of the subsequent set of NMR measurements, a subsequent saturation profile, a subsequent set of spatial T2 distributions, and an average pore throat size measurement; and
obtaining a peak T2 measurement by subtracting the subsequent set of spatial T2 distributions from the initial set of spatial T2 distributions.

18. The system according to claim 17, wherein the set of subsequent slice measures comprises a saturation interval.

19. The system according to claim 18. wherein the saturation interval has a width of from about 5% to about 15%.

20. The system according to claim 17, wherein the external force comprises a centrifugal force.
